(19) United States
(12) Patent Application Publication
(10) Pub. No.: US 2023/0402447 A1
(43) Pub. Date: Dec. 14, 2023

(54) DIODE ON HIGH RESISTANCE PORTION OF BULK SEMICONDUCTOR SUBSTRATE AND METHOD

(71) Applicant: GlobalFoundries U.S. Inc., Malta, NY (US)

(72) Inventors: Anindya Nath, Essex Junction, VT (US); Alain F. Loiseau, Williston, VT (US); Rajendran Krishnasamy, Essex Junction, VT (US); Souvick Mitra, Essex Junction, VT (US)

(21) Appl. No.: 17/806,797

(22) Filed: Jun. 14, 2022

(51) Int. Cl. H01L 27/02; H01L 29/87

(52) U.S. Cl. CPC H01L 27/0248; H01L 29/87

(57) ABSTRACT

Disclosed are a structure and method. The structure includes a substrate having monocrystalline lower and upper portions and a high resistance portion (e.g., a trap-rich amorphous portion) between the lower and upper portions. An isolation region extends through the upper portion, is above the high resistance portion, and is positioned laterally adjacent to a device section of the upper portion also above the high resistance portion. One or more devices (e.g., a diode, multiple diodes, a diode string, multiple diode strings, etc.) are on the trench isolation region, on the device section, and/or within the device section. The device(s) are separated from the lower portion by the high resistance portion and, potentially, by the isolation region or the device section. Such device(s) can be employed for electrostatic discharge (ESD) protection on RFIC chips and can sustain a larger RF voltage, provide area savings, reduce parasitic capacitance, improve harmonics, etc.

### BACKGROUND

### Field of the Invention

The present invention relates to semiconductor structures on bulk semiconductor substrates including one or more diodes and methods of forming the structures.

### Description of Related Art

On radio frequency integrated circuit (RFIC) chips, diodes and diode strings may be incorporated into electrostatic discharge (ESD) components for ESD protection of, for example, radio frequency (RF) switches. However, on RFIC chips formed from bulk semiconductor substrates, such diodes and diode strings can suffer from junction breakdown, poor voltage scaling, and harmonic distortion due to large RF swings, thereby limiting ESD protection.

### SUMMARY

Disclosed herein are embodiments of a structure. The structure can include a semiconductor substrate. The semiconductor substrate can have a first surface and a second surface opposite the first surface. The semiconductor substrate can further include a first portion adjacent to the first surface, a second portion adjacent to the second surface, and a third portion between the first portion and the second portion. The third portion can be high resistance portion. That is, the third portion can have a higher resistance than both the first portion and the second portion. The structure can further include a diode adjacent to the second surface of the semiconductor substrate such that it is separated from the first portion at least by the third portion (i.e., at least by the high resistance portion).

In some of the disclosed embodiment the structure can specifically include a string of diodes (i.e., multiple series-connected diodes, also referred to herein as a diode string). That is, in some embodiments the structure can include a semiconductor substrate. The semiconductor substrate can have a first surface and a second surface opposite the first surface. The semiconductor substrate can further include a first portion adjacent to the first surface, a second portion adjacent to the second surface, and a third portion between the first portion and the second portion. The third portion can be high resistance portion. That is, the third portion can have a higher resistance than both the first portion and the second portion. The structure can further include multiple series-connected diodes adjacent to the second surface of the semiconductor substrate such that they are separated from the first portion at least by the third portion (i.e., at least by the high resistance portion).

Also disclosed herein are method embodiments for forming the above-described structures. The method can include processing a semiconductor substrate so that the semiconductor substrate includes a first portion adjacent to a first surface, a second portion adjacent to a second surface opposite the first surface, and a third portion between the first portion and the second portion and specifically having a higher resistance than both the first portion and the second portion. The method can further include forming at least one diode (e.g., a single diode or a string of diodes). The diode(s) can further be formed adjacent to the second surface of the semiconductor substrate so as to be separated from the first portion at least by the third portion (i.e., by the high resistance portion).

### BRIEF DESCRIPTION OF THE SEVERAL VIEWS OF THE DRAWINGS

The present invention will be better understood from the following detailed description with reference to the drawings, which are not necessarily drawn to scale and in which:

FIGS. 1A-1 and 1A-2 are cross-section diagrams illustrating two embodiments of a semiconductor structure with one or more diodes above a high resistance portion of a bulk substrate;

FIGS. 1B-1 and 1B-2 are cross-section diagrams illustrating two additional embodiments of a semiconductor structure with one or more diodes above a high resistance portion of a bulk substrate;

FIGS. 1C-1 and 1C-2 are cross-section diagrams illustrating two more additional embodiments of a semiconductor structure with one or more diodes above a high resistance portion of a bulk substrate;

FIG. 2 is a schematic diagram illustrating a transceiver front-end of a RFIC chip with an ESD protection circuit;

FIG. 3A is a schematic diagram illustrating an ESD protection circuit that can incorporate one or more of the disclosed semiconductor structures and can replace the ESD protection circuit in the transceiver front-end of FIG. 2;

FIG. 3B is a cross-section diagram illustrating in one exemplary ESD protection circuit configured as illustrated in FIG. 3A;

FIG. 4A is a schematic diagram illustrating an ESD protection circuit that can incorporate one or more of the disclosed semiconductor structures and can replace the ESD protection circuit in the transceiver front-end of FIG. 2;

FIG. 4B is a cross-section diagram illustrating in one exemplary ESD protection circuit configured as illustrated in FIG. 4A;

FIG. 5 is a flow diagram illustrating method embodiments for forming the disclosed semiconductor structure embodiments;

FIGS. 6-14 are cross-section diagrams illustrating partially completed semiconductor structures for according to the flow diagram of FIG. 5; and

FIG. 15 is a cross-section diagram illustrating an exemplary semiconductor structure formed according to the flow diagram of FIG. 5 and including three different diode strings above a high resistance portion of a bulk semiconductor structure including: one on an isolation structure, one on a device section, and one within a device section.

### DETAILED DESCRIPTION

As mentioned above, on RFIC chips, diodes and diode strings may be incorporated into ESD components for ESD protection of, for example, RF switches. However, on RFIC chips formed from bulk semiconductor substrates, such diodes and diode strings can suffer from junction breakdown, poor voltage scaling, and harmonic distortion due to large RF swings, thereby limiting ESD protection.

In view of the foregoing, disclosed herein are embodiments of a semiconductor structure. The semiconductor structure can include a bulk semiconductor substrate. This bulk semiconductor substrate can include a lower portion, an upper portion, and a high resistance portion between the lower portion and the upper portion. The lower and upper portions can be monocrystalline and the high resistance portion can be, for example, a trap-rich layer such that it has a relatively high resistance as compared to the lower and upper portions. The semiconductor structure can further include a trench isolation region. The trench isolation region can extend through the upper portion, can be above the high resistance portion, and can laterally surround a device section, which is within the upper portion and, thus, also above the high resistance portion. The semiconductor structure can further include one or more diodes on the trench isolation region, on the device section, and/or within the device section. Thus, in the disclosed semiconductor structure embodiments, the diode(s) are separated from the lower portion of the substrate by the high resistance portion and, in some cases, by the trench isolation region or the device section of the upper portion. Such diode(s) can be incorporated, for example, into electrostatic discharge (ESD) protection structures on RFIC chips to sustain a larger RF voltage, to provide area savings, to reduce parasitic capacitance, to improve harmonics, etc. Also disclosed herein are method embodiments for forming the above-described semiconductor structures.

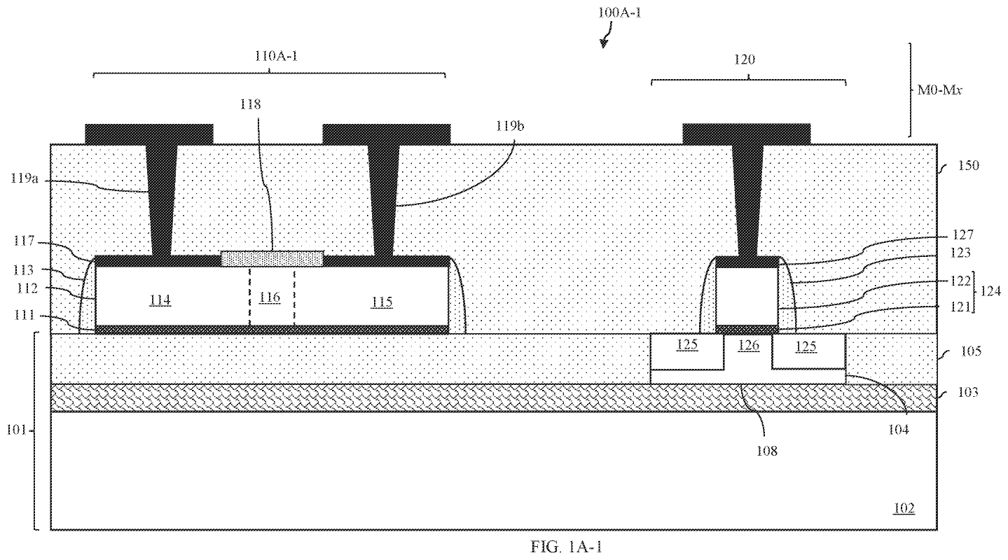

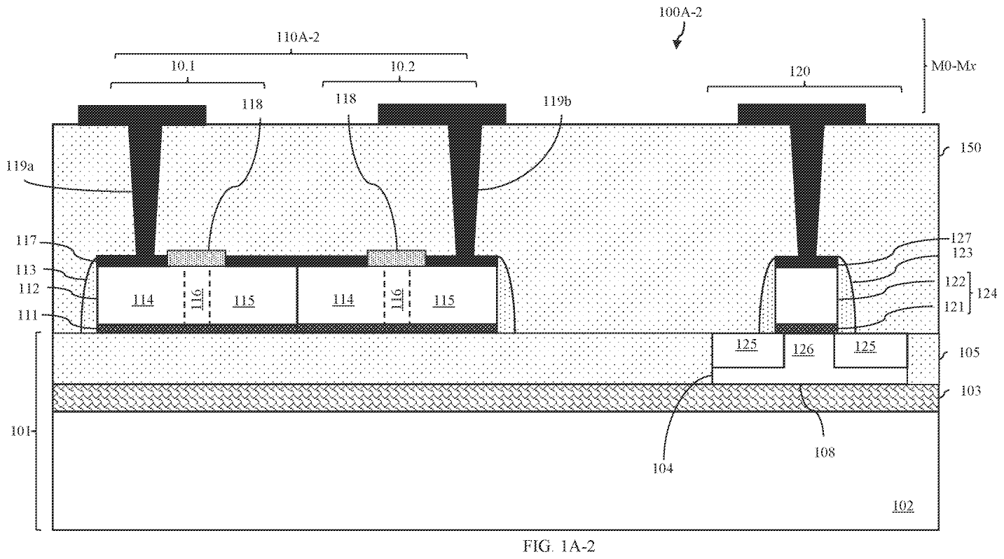

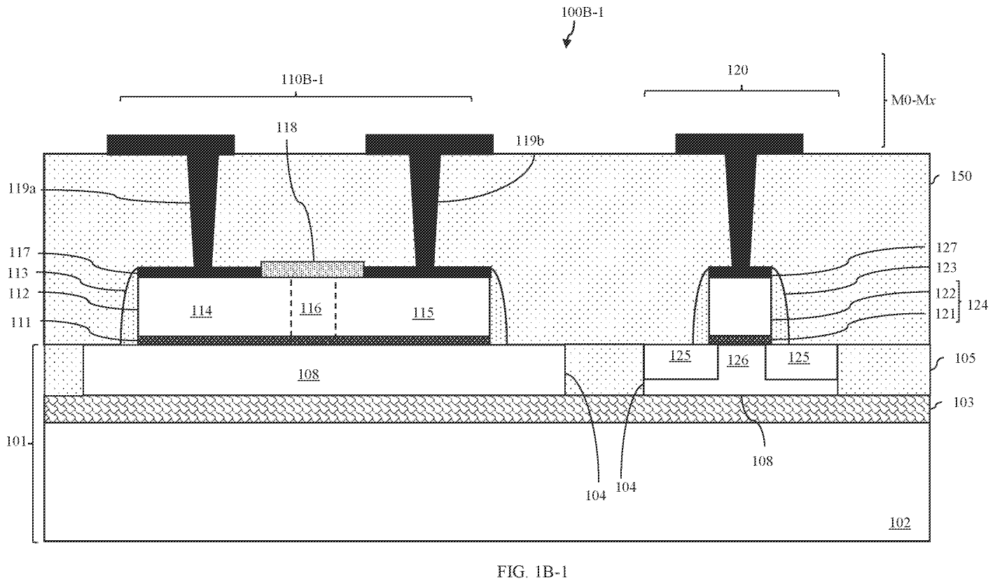

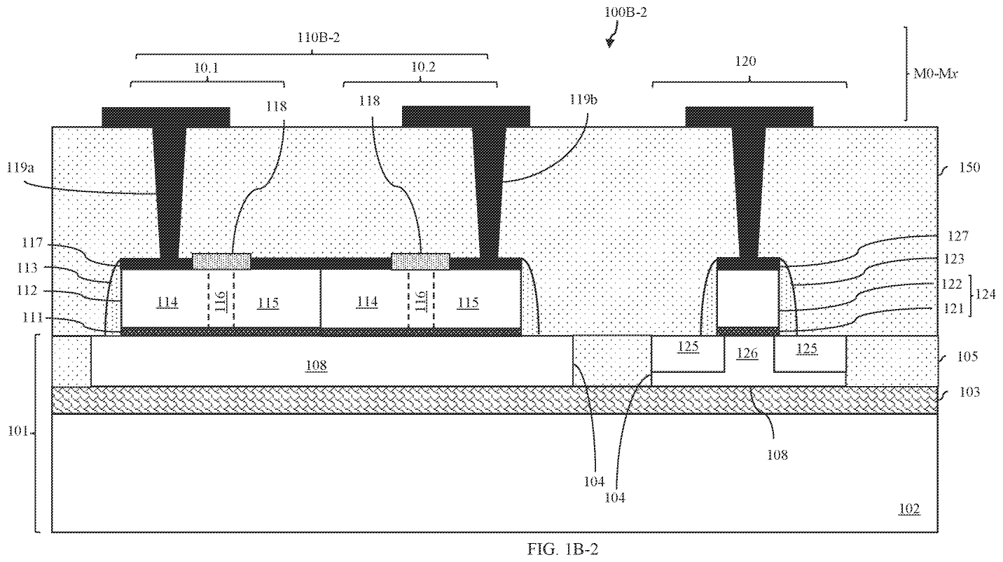

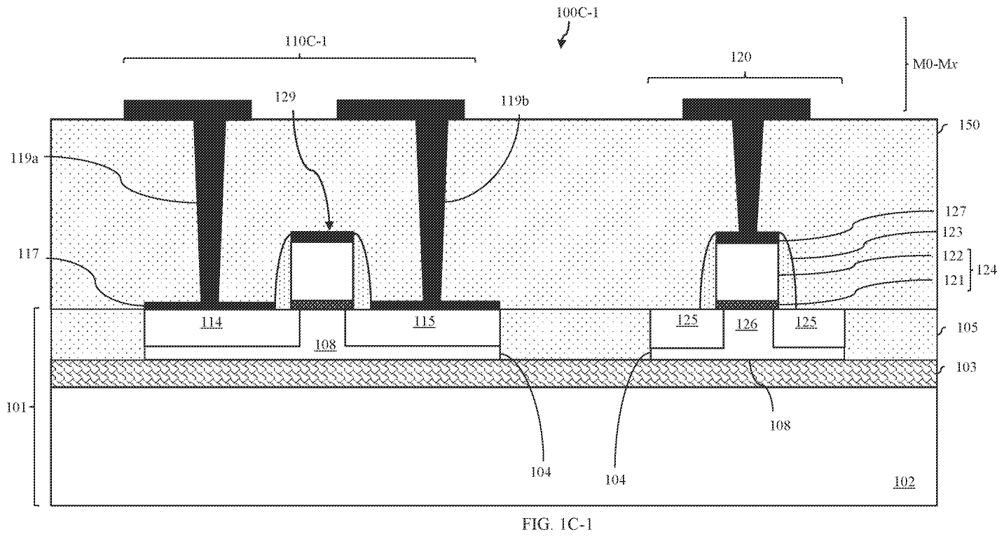

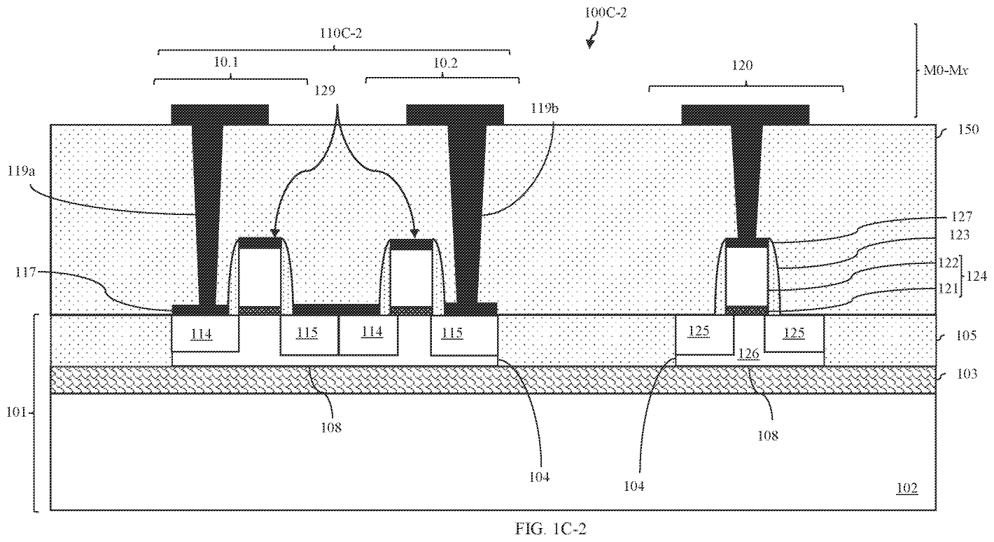

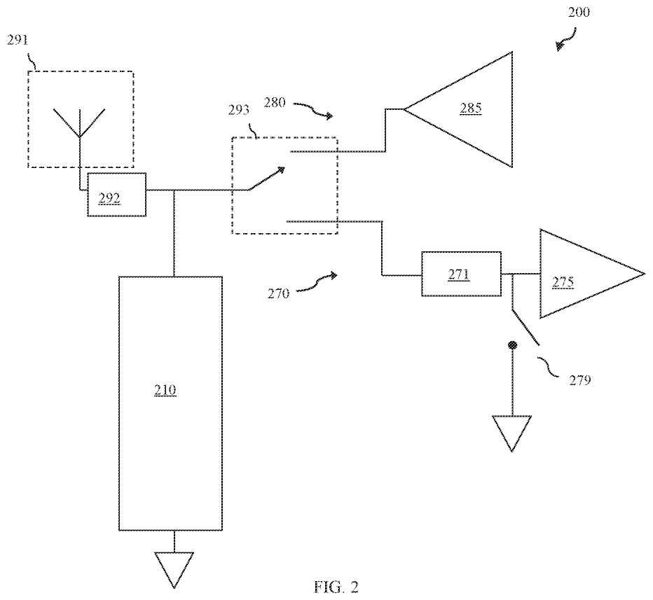

Referring to FIGS. 1A-1, 1A-2, 1B-1, 1B-2, 1C-1, and 1C-2, disclosed herein are embodiments of a semiconductor structure 100A-1, 100A-2, 100B-1, 100B-2, 100C-1, and 100C-2. The semiconductor structure 100A-1, 100A-2, 100B-1, 100B-2, 100C-1, and 100C-2 can include a bulk semiconductor substrate 101. This bulk semiconductor substrate 101 can be, for example, a bulk silicon substrate or a bulk semiconductor substrate of some other suitable semiconductor material.

The bulk semiconductor substrate 101 can have a first surface (referred to herein as bottom surface) and a second surface (referred to herein as a top surface) opposite the first surface. The bulk semiconductor substrate 101 can further include a first portion 102 (referred to herein as a lower portion) adjacent to the bottom surface, a second portion 104 (referred to herein as an upper portion) adjacent to the top surface, and a third portion 103 (referred to herein as a high resistance portion or trap-rich layer) between the lower portion 102 and the upper portion 104. The high resistance portion 103 can have a higher resistance than both the lower portion 102 and the upper portion 104. Specifically, the lower portion 102 and the upper portion 104 can both be monocrystalline in structure and the high resistance portion 103 can be a trap-rich layer between the lower and upper portions. For example, the high resistance portion 103 can include a defect layer between the monocrystalline lower and upper portions 102 and 104. This defect layer can be polycrystalline or amorphous in structure and can include imperfections in the regular spacing of atoms that make up the semiconductor material. These imperfections form traps and, specifically, locations within the semiconductor substrate that restrict movement of charge carriers (i.e., electrons and holes) so that this portion is referred to as being a trap-rich portion or layer. In any case, the presence of these imperfections or traps increases resistance.

As discussed in greater detail below regarding the method embodiments, an exemplary technique for forming such a high resistance portion 103 in a semiconductor substrate 101 can include implantation of an inert dopant to modify the crystalline structure (e.g., to amorphized the crystalline structure) of a middle portion of the semiconductor substrate. For purposes of this disclosure, an inert dopant refers to a dopant species that is generally not considered to be chemically reactive (i.e., that is neutral) at least with respect to the monocrystalline semiconductor material (e.g., monocrystalline silicon) within which it is implanted during processing, a dopant species that is capable of modifying the crystalline structure of that monocrystalline semiconductor material during the implantation process (e.g., to create an amorphous region), a dopant species that doesn't completely prevent recrystallization of the doped region during a subsequent rapid thermal anneal process (RTA) (e.g., to create poly and/or monocrystalline region(s)), and a dopant species that doesn't significantly impact the electrical properties of the resulting poly and/or monocrystalline region(s). Such inert dopants include, but are not limited to, inert gases (also referred to as noble gases) (e.g., argon, xenon, helium, neon, krypton, radon, etc.), silicon, or any other suitable inert dopant. The inert dopant implantation process is followed by a recrystallization anneal during which the amorphized portion begins to recrystallize from the top down and from the bottom up and, as a result, the defect layer is formed in the middle between the top and bottom. Thus, the semiconductor substrate will include the inert dopant below, within, and above the high resistance portion 103.

The semiconductor structure 100A-1, 100A-2, 100B-1, 100B-2, 100C-1, and 100C-2 can further include isolation regions 105 that extend from the top surface of the semiconductor substrate 101 through the upper portion 104 down to or close to the high resistance portion 103. The isolation regions 105 can be, for example, shallow trench isolation (STI) regions. The STI regions can include trenches, which extend into the semiconductor substrate 101 from the top surface and which define the boundaries of and, particularly, laterally surround one or more device sections 108 in the upper portion 104 of the semiconductor substrate 101. The STI regions can further include one or more layers of isolation material (e.g., silicon dioxide, silicon nitride, silicon oxynitride, etc.) filling the trenches. Optionally, each device section 108 defined by the STI regions 105 can doped to have either P-type conductivity or N-type conductivity at a relatively low conductivity level (e.g., to include a low-doped Pwell or Nwell).

The semiconductor structure can further include at least one device and, particularly, at least one diode (e.g., see the diode 110A-1 in the structure 100A-1 of FIG. 1A-1, the diode 110B-1 in the structure 100B-1 of FIG. 1B-1, and the diode 110C-1 in the structure 100C-1 of FIG. 1C-1). In some embodiments, the semiconductor structure can include multiple series-connected devices and, particularly, multiple series-connected diodes (i.e., a string of diodes, also referred to herein as a diode string) (e.g., see the series-connected diodes 10.1-10.2 in the diode string 110A-2 in the structure 100A-2 of FIG. 1A-2, the series-connected diodes in the diode string 110B-2 in the structure 100B-2 of FIG. 1B-2, and the series-connected diodes 10.1-10.2 the diode string 110C-2 in the structure 100C-2 of FIG. 1C-2). For purposes of illustration, only two series-connected diodes 10.1-10.2 are shown in the diode string 110A-2 of FIG. 1A-2, 110B-2 of FIG. 1B-2, and 110C-2 of FIG. 1C-2. However, it should be understood the figures are not intended to be limiting and such diode strings can include any number of two or more series-connected diodes.

Each diode (i.e., each discrete diode 110A-1, 110B-1, 110C-1 or each diode 10.1-10.2 in a diode string 110A-2, 110B-2, 110C-2) can include a P-type semiconductor region 115 and an N-type semiconductor region 114, which is positioned laterally adjacent to the P-type semiconductor region 115. The P-type semiconductor region 115 can, for example, be doped so as to have P-type conductivity at a relatively high conductivity level (e.g., so as to be a P+ semiconductor region). The N-type semiconductor region 114 can, for example, be doped so as to have N-type conductivity at a relatively high conductivity level (e.g., so as to be an N+ semiconductor region). See the more detailed discussion below regarding semiconductor materials and dopants used to achieve different conductivity types and levels. Furthermore, any diode in the disclosed structures can be a PN diode in which the P-type semiconductor region 115 is positioned laterally immediately adjacent to the N-type semiconductor region 114. Alternatively, any diode in the disclosed structures can include and additional semiconductor region 116 positioned laterally between and separating the P-type semiconductor region 115 and the N-type semiconductor region 114, as illustrated. Thus, for example, any diode in the disclosed structures could be a PIN diode with the additional semiconductor region 116 being an intrinsic semiconductor region (i.e., an undoped semiconductor region). Alternatively, the additional semiconductor region 116 could be low-doped having either the P-type conductivity at a lower conductivity level than the P-type semiconductor region 115 or the N-type conductivity at a lower conductivity level than the N-type semiconductor region 114.

In any case, each diode (i.e., each discrete diode 110A-1, 110B-1, 110C-1 or each diode 10.1-10.2 in a diode string 110A-2, 110B-2, 110C-2) can be located adjacent to the top surface of the semiconductor substrate 101 (i.e., on that side of the substrate) such that it is separated from the lower portion 102 of the semiconductor substrate 101 at least by the high resistance portion 103. Thus, for example, each diode (i.e., each discrete diode 110A-1, 110B-1, 110C-1 or each diode 10.1-10.2 in a diode string 110A-2, 110B-2, 110C-2) can be located on an STI region 105 within the upper portion 104 (e.g., see the semiconductor structures 110A-1 and 110A-2 of FIGS. 100A-1 and 100A-2, respectively), on a device section 108 of the upper portion 104 (e.g., see the semiconductor structures 110B-1 and 110B-2 of FIGS. 100B-1 and 100B-2, respectively), or within a device section 108 of the upper portion 104 (e.g., see the semiconductor structures 110C-1 and 110C-2 of FIGS. 100C-1 and 100C-2, respectively).

More particularly, referring to the semiconductor structure 100A-1 of FIG. 1A-1 and 100A-2 of FIG. 1A-2 where a diode or diode string is above the STI region 105. In this case, a dielectric layer 111 can be above and immediately adjacent to the top surface of an STI region 105. The dielectric layer 111 can include one or more layers of dielectric materials. The diode 110A-1 of FIG. 1A-1 and the diode string 110A-2 (including diodes 10.1-10.2) of FIG. 1A-2 can include a polycrystalline semiconductor layer 112 on the dielectric layer 111. The polycrystalline semiconductor layer 112 and the dielectric layer 111 can be lithographically patterned and etched during processing so as to have, for example, an elongated rectangular shape with opposing sidewalls and opposing end walls above the STI region 105. Dielectric sidewall spacers 113 can be positioned laterally adjacent to the sidewalls and end walls. For each diode, the P-type semiconductor region 115 and the N-type semiconductor region 114 are P-type and N-type dopant implant regions, respectively, within the polycrystalline semiconductor layer 112 such that they are polycrystalline in structure. An optional additional semiconductor region 116 (e.g., an intrinsic or undoped semiconductor region) can also be within the polycrystalline semiconductor layer 112 positioned laterally between the P-type and N-type semiconductor regions of a given diode. Furthermore, in the case of a diode string, the P-type semiconductor region 115 of one diode (e.g., in the diode 10.1) can abut the N-type semiconductor region 114 of the next diode in the string (e.g., diode 10.2) (e.g., as illustrated in the semiconductor structure 100A-2 of FIG. 1A-2). Alternatively, the P-type semiconductor region 115 of one diode (e.g., in the diode 10.1) can be physically separated from the N-type semiconductor region 114 of the next diode in the string (e.g., diode 10.2). In either case, the P-type semiconductor region 115 of one diode and the N-type semiconductor region 114 of the next diode in the diode string can be electrically connected by a local interconnect (e.g., a silicide layer 117 on the top surface of the polysilicon semiconductor layer 112 and extending across the interface between the P-type semiconductor region 115 and the N-type semiconductor region 114 of two adjacent diodes without further extending across the interface between P-type and N-type semiconductor regions within any individual diode). With this configuration, the diode 110A-1 in the semiconductor structure 100A-1 of FIG. 1A-1 and the diode string 110A-2 in the semiconductor structure 100A-2 of FIG. 1A-2 are separated from the lower portion 102 of the semiconductor substrate 101 by the dielectric layer 111, the STI region 105, and the high resistance portion 103, which all provide isolation from the lower portion 102.

Referring to the semiconductor structure 100B-1 of FIG. 1B-1 and 100B-2 of FIG. 1B-2, in this case, the diode 110B-1 and diode string 110B-2 can be configured essentially the same as the diode 110A-1 and diode string 110A-2, respectively, except that instead of being above an STI region 105, they are above a device section 108 of the upper portion 104 of the semiconductor substrate. That is, in these semiconductor structures, a dielectric layer 111 can be above and immediately adjacent to the top surface of a device section 108 and, optionally, the device section 108 can include well region (e.g., a Pwell). The dielectric layer 111 can include one or more layers of dielectric materials. The diode 110B-1 of FIG. 1B-1 and the diode string 110B-2 (including diodes 10.1-10.2) of FIG. 1A-2 can include a polycrystalline semiconductor layer 112 on the dielectric layer 111. The polycrystalline semiconductor layer 112 and the dielectric layer 111 can be lithographically patterned and etched during processing so as to have, for example, an elongated rectangular shape with opposing sidewalls and opposing end walls above the device section 108 of the upper portion 104 of the semiconductor substrate 101. Dielectric sidewall spacers 113 can be positioned laterally adjacent to the sidewalls and end walls. For each diode, the P-type semiconductor region 115 and the N-type semiconductor region 114 are P-type and N-type dopant implant regions, respectively, within the polycrystalline semiconductor layer 112 such that they are polycrystalline in structure. An optional additional semiconductor region 116 (e.g., an intrinsic or undoped semiconductor region) can also be within the polycrystalline semiconductor layer 112 positioned laterally between the P-type and N-type semiconductor regions of a given diode. Furthermore, in the case of a diode string, the P-type semiconductor region 115 of one diode (e.g., in the diode 10.1) can abut the N-type semiconductor region 114 of the next diode in the string (e.g., diode 10.2) (e.g., in the semiconductor structure 100B-2 of FIG. 1B-2). Alternatively, the P-type semiconductor region 115 of one diode (e.g., in the diode 10.1) can be physically separated from the N-type semiconductor region 114 of the next diode in the string (e.g., diode 10.2). In either case, the P-type semiconductor region 115 of one diode and the N-type semiconductor region 114 of the next diode in the diode string can be electrically connected by a local interconnect (e.g., a silicide layer 117 on the top surface of the polysilicon semiconductor layer extending across the interface between the P-type semiconductor region 115 and the N-type semiconductor region 114 of two adjacent diodes without further extending across the interface between P-type and N-type semiconductor regions within any individual diode). With this configuration, the diode 110B-1 in the semiconductor structure 100B-1 of FIG. 1B-1 and the diode string 110B-2 in the semiconductor structure 100B-2 of FIG. 1B-2 are separated from the lower portion 102 of the semiconductor substrate 101 by the dielectric layer 111, the device section 108 with optional Pwell, and the high resistance portion 103. The dielectric layer 111 can isolate the diode/diode string from the device section 108 and the dielectric layer 111, the optional Pwell in the device section 108, and the high resistance portion 103 can provide isolation from the lower portion 102.

It should be noted that the dielectric layer 111 and the polycrystalline semiconductor layer 112 can be patterned, during processing, from the same materials used in the formation of other devices (e.g., resistors) or components (e.g., gate structures of field effect transistors (FETs)) elsewhere on the semiconductor substrate 101. Thus, for example, in some embodiments the dielectric layer 111 can include one or more layers of gate dielectric material including, but not limited to, silicon dioxide, silicon oxynitride, a high-K gate dielectric (e.g., hafnium oxide, hafnium silicon oxide, hafnium silicon oxynitride, hafnium aluminum oxide, aluminum oxide, tantalum oxide, zirconium oxide, etc.) or any other suitable gate dielectric material. The polycrystalline semiconductor layer 112 can be, for example, a polycrystalline semiconductor material suitable for use as a gate conductor material (when doped) (e.g., a polysilicon, polysilicon germanium, etc.).

Referring to the semiconductor structure 100C-1 of FIG. 1C-1 and 100C-2 of FIG. 1C-2, in this case, the diode 110C-1 and diode string 110C-2 are within the device section 108 of the upper portion 104 of the semiconductor substrate 101 instead of being above it. That is, in these semiconductor structures, the P-type semiconductor region 115 and the N-type semiconductor region 114 of each diode can be P-type and N-type dopant implant regions within the device section 108 such that they are monocrystalline in structure. Alternatively, the P-type semiconductor region 115 and the N-type semiconductor region 114 could in situ doped semiconductor layers selectively epitaxially grown with trenches in the device section 108 such that they are monocrystalline. As mentioned above, optionally, a device section 108 can include a doped well region (e.g., a Pwell with a lower P-type conductivity than the P-type semiconductor region 115 or, alternatively, an Nwell with a lower N-type conductivity than the N-type semiconductor region). In this case, the P-type semiconductor region 115 and the N-type semiconductor region 114 can be formed within the doped well region. Optionally, in a given diode, the P-type semiconductor region 115 and the N-type semiconductor region 114 can be separated by a portion of the device section 108 (e.g., by an intrinsic portion or by a doped well portion, if applicable). In the case of a diode string, the P-type semiconductor region 115 of one diode (e.g., in the diode 10.1) can abut the N-type semiconductor region 114 of the next diode in the string (e.g., diode 10.2) (e.g., in the semiconductor structure 100C-2 of FIG. 1C-2). Alternatively, the P-type semiconductor region 115 of one diode (e.g., in the diode 10.1) can be physically separated from the N-type semiconductor region 114 of the next diode in the string (e.g., diode 10.2). In either case, the P-type semiconductor region 115 of one diode and the N-type semiconductor region 114 of the next diode in the diode string can be electrically connected by a local interconnect (e.g., a silicide layer 117 on the top surface of the device section 108 and extending across the interface by the P-type semiconductor region 115 and the N-type semiconductor region 114 of two adjacent diodes without further extending across the interface between P-type and N-type semiconductor regions within any individual diode). With this configuration, the diode 110C-1 in the semiconductor structure 100C-1 of FIG. 1C-1 and the diode string 110C-2 in the semiconductor structure 100C-2 of FIG. 1C-2 are separated from the lower portion 102 of the semiconductor substrate 101 and the high resistance portion 103 of the semiconductor substrate 101.

As mentioned above, in semiconductor structures with diode strings (e.g., see the diode string 110A-2 of the semiconductor structure 100A-2 of FIG. 1A-2, diode string 110B-2 of the semiconductor structure 100B-2 of FIG. 1B-2, and diode string 110C-2 of the semiconductor structure 100C-2 of FIG. 1C-2), a local interconnect (e.g., a silicide layer 117) can electrically connect the P-type semiconductor region 115 of one diode and the N-type semiconductor region 114 of the next diode in the diode string. Additionally, each semiconductor structure 100A-1, 100A-2, 100B-1, 100B-2, 100C-1 and 100C-2 can include metal silicide layers 117 on each P-type semiconductor region 115 and N-type semiconductor region 114. These metal silicide layers 117 can be, for example, layers of cobalt silicide (CoSi), nickel silicide (NiSi), tungsten silicide (WSi), titanium silicide (TiSi), or any other suitable metal silicide material.

Additionally, each semiconductor structure 100A-1, 100A-2, 100B-1, 100B-2, 100C-1 and 100C-3 can include an isolation structure on each diode (i.e. diode 110A-1, 110B-1, 110C-1 or on diodes 10.1-10.2 in a diode string 110A-2, 110B-2, 110C-2) above the interface between the P-type semiconductor region 115 and the N-type semiconductor region 114 of that diode (i.e., above and extending across the PN junction or the PIN junction). The isolation structure on each diode can prevent silicide formation over the PN or PIN junction of a diode during processing and, thereby prevent shorting of the P-type and N-type semiconductor regions. Specifically, the isolation structure on each diode can extend laterally between metal silicide layers 117 on the P-type semiconductor region 115 and the N-type semiconductor region 114 of a given diode. The isolation structure 118 can, for example, be a dielectric layer or stack of dielectric layers (e.g., see the isolation structure 118 on the diode 110A-1 of the semiconductor structure 100A-1 of FIG. 1A-1, the isolation structures 118 on the diode string 110A-2 of the semiconductor structure 100A-2 of FIG. 1A-2, the isolation structure 118 on the diode 110B-1 of the semiconductor structure 100B-1 of FIG. 1B-1, and the isolation structures 118 on the diode string 110B-2 of the semiconductor structure 100B-2 of FIG. 1B-2). The dielectric layer of an isolation structure 118 can be, for example, a salicide blocking layer, such as a silicon nitride (SiN) layer, a silicon carbon nitride (SiCN) layer, a silicon oxynitride (SiON) layer, etc. It should be noted that the diode 110C-1 of the semiconductor structure 100C-1 of FIG. 1C-1 and the diode string 110C-2 of the semiconductor structure 100C-2 of FIG. 1C-2 could similarly include isolation structure(s) 118 comprising a dielectric layer or stack of dielectric layers, as described above. However, alternatively, since the diode/diode string is within the device section 108, the isolation structure on each diode in the semiconductor structures 100C-1 and 100C-2 could be a non-contacted dummy gate structure 129 (including, for example, a gate dielectric layer, gate polycrystalline semiconductor layer, and gate sidewall spacers) that effectively function as an isolation structure, as described above.

The semiconductor structure 100A-1, 100A-2, 100B-1, 100B-2, 100C-1, and 100C-2 can further include one or more layers of middle of the line (MOL) dielectric material 150 covering the diode or diode string. These layer(s) of MOL dielectric material 150 can include, but are not limited to, a relatively thin conformal dielectric layer (also referred to herein as an etch stop layer). This relatively thin conformal dielectric layer can be made of silicon nitride or some other suitable etch stop material. These layer(s) of MOL dielectric material 150 can also a blanket layer of interlayer dielectric (ILD) material. This ILD material can be, for example, silicon dioxide, doped silicon glass (e.g., phosphosilicate glass (PSG) or borophosphosilicate glass (BPSG)), or any other suitable ILD material.

The semiconductor structure 100A-1, 100A-2, 100B-1, 100B-2, 100C-1, and 100C-2 can further include a cathode contact 119a and an anode contact 119b extending essentially vertically through the MOL dielectric material 150. In the semiconductor structure 100A-1, 100B-1, and 100C-1, the cathode contact 119a and the anode contact 119b can extend vertically through the MOL dielectric material 150 to the silicide layers on the N-type semiconductor region 114 and the P-type semiconductor region 115 of the diode 110A-1, 110B-1, and 110C-1, respectively. In the semiconductor structure 100A-2, 100B-2, and 100C-2, the cathode contact 119a can extend vertically through the MOL dielectric material 150 to the silicide layer on the N-type semiconductor region 114 of a first diode (e.g., 10.1) at one end of the diode string 110A-2, 110B-2 and 110C-2 and the anode contact 119b can extend vertically through the MOL dielectric material 150 to the silicide layer on the P-type semiconductor region 115 of a last diode (e.g., 10.2) at the opposite end of the diode string 110A-2, 110B-2 and 110C-2, respectively. The cathode contact 119a and the anode contact 119b can be electrically connected to other on-chip components through wires in the back-end-of-the-line (BEOL) metal levels (MI-Mx). Thus, for example, any diode or diode string located on an isolation region, on a device section, or within a device section can also be electrically connected (e.g., through MOL and BEOL interconnects) with any other diode or diode string, any other device and/or any other on-chip circuit located elsewhere on the substrate.

The semiconductor structure 100A-1, 100A-2, 100B-1, 100B-2, 100C-1 and 100C-2 can further include one or more additional devices 120 formed using a device section 108. The additional device(s) 120 can include passive or active semiconductor devices. For example, an additional device 120 can include a field effect transistor (FET). An exemplary FET can include a channel region 126, which is in the device section 108 and has a first-type conductivity and which is positioned laterally between source/drain regions 125 having a second-type conductivity that is different from the first-type conductivity. The FET can be an N-type FET (NFET) or a P-type FET (PFET). In the case of an NFET, the first-type conductivity can be P-type conductivity and the second-type conductivity can be N-type conductivity, whereas in the case of a PFET, the first-type conductivity can be N-type conductivity and the second-type conductivity can be P-type conductivity. The FET can further include a gate structure 124. The gate structure 124 can include a gate stack including a gate dielectric layer 121, a gate conductor layer 122 on the gate dielectric layer 121, and a silicide layer 127 on the gate conductor layer 122. The gate structure can also include gate sidewall spacers 123 positioned laterally adjacent to sidewalls of the gate stack. Alternatively, the additional device could include a FET with some other configuration or some other type of active or passive device.

As mentioned above, one or more of the diode or diode string structures 110A-1 to 110C-2 described above and illustrated in FIGS. 1A-1 to 1C-2 could be included on the same bulk semiconductor substrate 101 as and optionally interconnected (e.g., through the BEOL metal levels) with each other and/or with another device or on-chip circuit.

For example, FIG. 2 is a schematic diagram illustrating a transceiver front-end 200 of a RFIC chip. This transceiver front-end 200 includes a transmitter branch 280 and a receiver branch 270. A switch 293 can selectively and alternatively connect the transmitter branch 280 or the receiver branch 270 to an input/output pad 292 that is electrically connected to an antenna 291. The transmitter branch 280 can include a power amplifier 285. The receiver branch 270 can include a low noise amplifier 275, an impedance matching network 271 between the switch 293 and the low noise amplifier 275, and another switch 279 (e.g., a shunt device) connected between the input of the low noise amplifier 275 and ground. The transceiver front-end 200 can also include an electrostatic discharge (ESD) protection structure 210 (also referred to as an ESD protection circuit) connected to a node on the interconnect between the input/output pad 292 and the switch 293 in order to protect the switch 293, the switch 279 and other components in the transceiver front-end 200 from damage due to ESD.

Also disclosed herein are embodiments of an ESD protection structure including one or more of the diode or diode string structures 110A-1 to 110C-2, as described above and illustrated in FIGS. 1A-1 to 1C-2, above a high resistance portion 103 of a bulk semiconductor substrate 101.

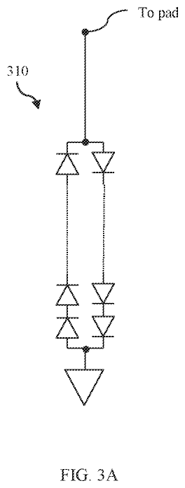

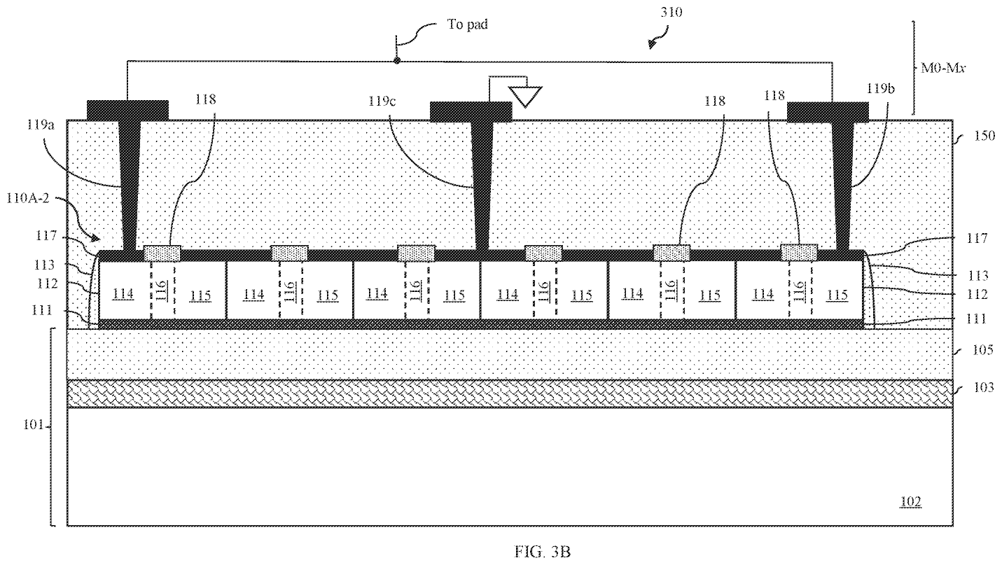

For example, FIG. 3A is a schematic diagram illustrating an exemplary ESD protection structure 310 (also referred to as an ESD protection circuit) that can replace the ESD protection structure 210 of FIG. 2. As illustrated, this ESD protection circuit 310 includes a diode string connected in a continuous loop. One cathode-to-anode intersection (i.e., one N-type semiconductor region-to-P-type semiconductor region intersection) between a pair of adjacent diodes within the loop can be connected to ground. Another cathode-to-anode intersection (i.e., another N-type semiconductor region-to-P-type semiconductor region intersection) between another pair of adjacent diodes within the loop can be electrically connected to an input/output pad or a power pad (e.g., to the input/output pad 292 of the transceiver front-end 200 of FIG. 2). Such an ESD protection circuit 310 could be formed by incorporating additional diodes into any of the diode strings 110A-2, 110B-2, and 110C-2 described above and using BEOL metal level wiring to form the required electrical connections.

FIG. 3B is a cross-section diagram illustrating the exemplary ESD protection structure 310 with additional diodes incorporated into the diode string 110A-2. As discussed in detail above, such a diode string 110A-2 is on an STI region 105, which is extend through an upper portion 104 of the semiconductor substrate 101 and which above a high resistance portion 103 of the semiconductor substrate 101. The ESD protection structure 310 further includes various electrical connections in the BEOL metal level wiring. Specifically, through BEOL metal level wiring, the cathode contact 119a on the N-type semiconductor region 114 of a first diode at one end of the diode string 110A-2 and an anode contact 119b on the P-type semiconductor region 115 of a last diode at the opposite end of the diode string 110A-2 are electrically connected to create a looped diode string. The cathode contact 119a and the anode contact 119b are further electrically connected to an input/output pad or a power pad (e.g., to the input/output pad 293 of the transceiver front-end 200 of FIG. 2). Furthermore, through BEOL metal level wiring and an additional MOL contact 119c, the intersection between the N-type semiconductor region 114 and the P-type semiconductor region 115 of adjacent diodes at the center of the diode string 110A-2 can be connected to ground. Alternatively, some a different type of diode string with a similar BEOL metal level wiring configuration could be used to form the ESD protection structure 310.

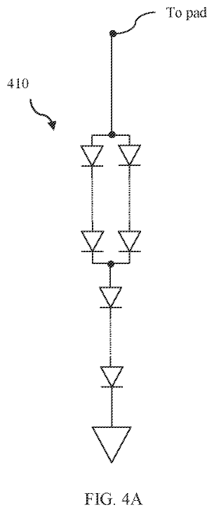

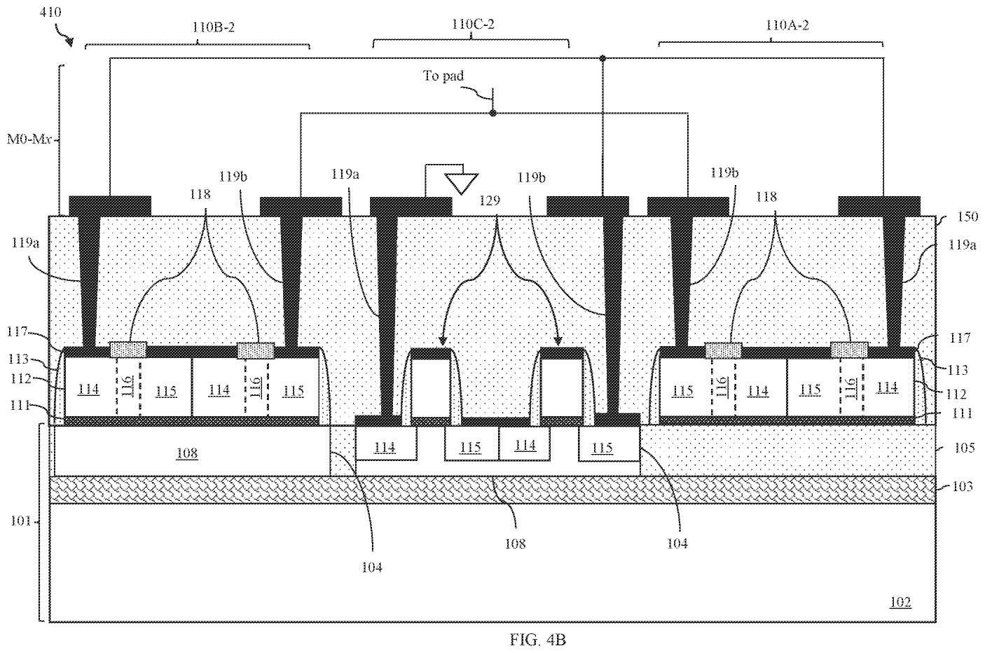

For example, FIG. 4A is a schematic diagram illustrating an exemplary ESD protection structure 410 (also referred to as an ESD protection circuit) that can replace the ESD protection structure 210 of FIG. 2. As illustrated, this ESD protection 410 includes two parallel-connected diodes strings and an additional diode string. The parallel-connected diode strings can have anodes (i.e., P-type semiconductor regions 115) of diodes at one end electrically connected to each other and to an input/output pad or a power pad (e.g., to the input/output pad 292 of the transceiver front-end 200). Cathodes (i.e., N-type semiconductor regions 114) of diodes at the opposite end can be electrically connected to each other. The additional diode string can have an anode of a diode at one end electrically connected to the joined cathodes of the parallel-connected diode strings and a cathode of a diode at the opposite end electrically connected to ground. Such an ESD protection circuit 410 could be formed by incorporating additional diodes into multiple ones of the diode strings 110A-2, 110B-2, and/or 110C-2 as described above and using further using BEOL metal level wiring to form the required electrical connections.

FIG. 4B is a cross-section diagram illustrating the exemplary ESD protection structure 410 including multiple sets of series-connected diodes including a diode string 110A-2 (i.e., on an STI region 105 above a high resistance portion 103 of the semiconductor substrate 101), a diode string 110B-2 (i.e., on a device section 108 of the upper portion 104 of the semiconductor substrate 101 above a high resistance portion 103 of the semiconductor substrate 101) and a diode string 110C-2 (i.e., within a device section 108 and above a high resistance portion 103). The ESD protection structure further includes various interconnects formed in the BEOL metal levels. Specifically, in this structure 410 through BEOL metal level wiring, the diode string 110A-2 and the diode string 110B-2 can be connected in parallel. That is, the cathode contact 119a and anode contact 119b on the diode string 110A-2 can be electrically connected through BEOL metal level wiring to the cathode contact 119a and the anode contact 119b of the diode string 110B-2, respectively. The cathode contacts 119a of the parallel-connected diode strings 110A-2 and 110B-2 can further be electrically connected to an input/output pad to power pad (e.g., to the input/output pad 292 of the transceiver front-end 200 of FIG. 2). The cathode contact 119a on the diode string 110C-2 can further be electrically connected through BEOL metal level wiring to ground and the anode contact 119b on the diode string 110C-2 can be electrically connected to the cathode contacts 119a on the parallel-connected diode strings 110A-2 and 110B-2. Alternatively, some other combination of diode strings of different types with a similar BEOL metal level wiring configuration could be used to form the ESD protection structure 410.

The exemplary ESD protection structures 310, 410 described above and illustrated in FIGS. 3A-3B and 4A-4B are provided for illustration purposes and are not intended to be limiting. The disclosed ESD protection structures can include various other circuit configurations with one or more diodes or diode strings above an STI region 105 on a high resistance portion 103 of a semiconductor substrate 101, above a device section 108 on a high resistance portion 103 of a semiconductor substrate 101 and/or within a device section 108 of a high resistance portion 103 of a semiconductor substrate 101.

Advantages associated with incorporating the disclosed diode and/or diode string structures into electrostatic discharge (ESD) protection structures on RFIC chips include, but are not limited to, sustaining a larger RF voltage, providing an area savings, reducing parasitic capacitance, and improve harmonics.

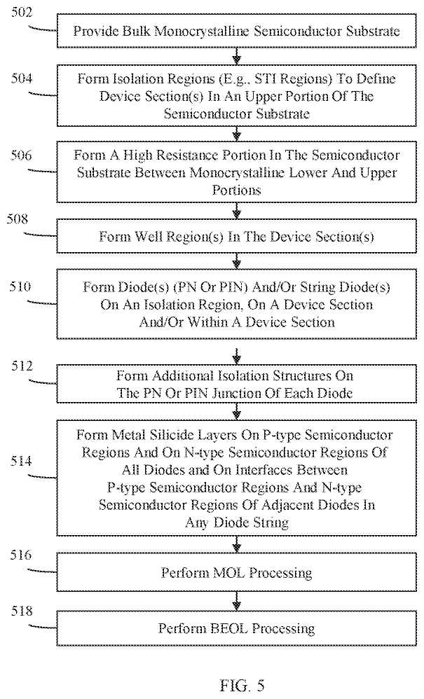

Referring to the flow diagram of FIG. 5, also disclosed herein are method embodiments for forming the above-described semiconductor structures. For purposes of illustration, the method is described below and illustrated in the drawings with regard to the formation of a semiconductor structure, such as the semiconductor structure of FIG. 4B, that includes a semiconductor substrate 101 with a high resistance portion 103 between monocrystalline lower and upper portions 102 and 104 and that further includes multiple sets of series-connected diodes (i.e., multiple diode strings) including a diode string in area A on an STI region 105 above the high resistance portion 103 (e.g., a diode string 110A-2), another diode string in area B on a device section 108 of the upper portion 104 above the high resistance portion 103 (e.g., a diode string 110B-2), and yet another diode string in area C within a device section 108 above the high resistance portion 103 (e.g., a diode string 110C-2). It should be understood the figures and description thereof are not intended to be limiting. Alternatively, the same or similar processes could be used to form any one or more of the disclosed diodes or diode strings above an STI region 105, above a device section 108, and/or within a device section 108 and, thereby above the high resistance portion 103 of the semiconductor substrate 101.

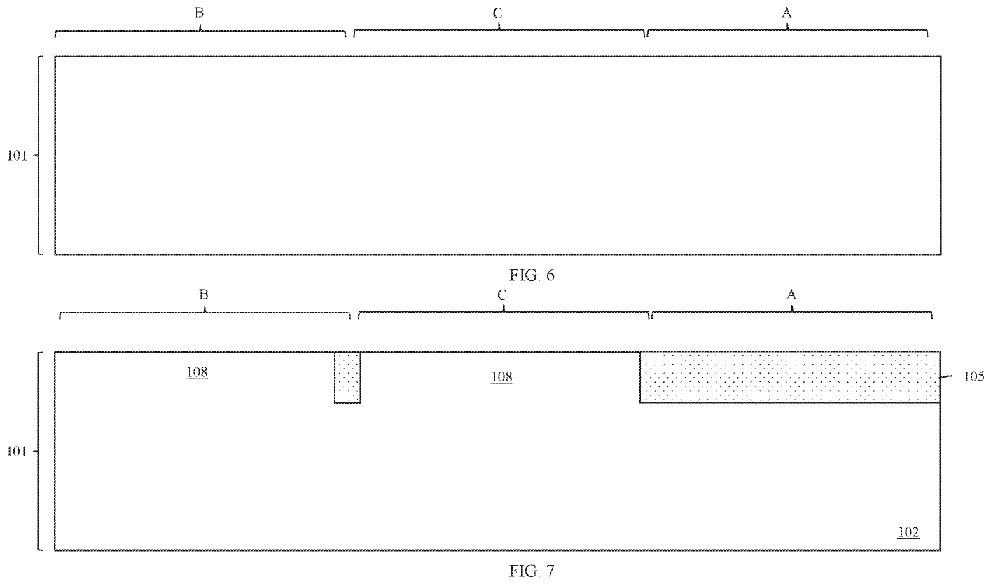

The method can include providing a bulk semiconductor substrate 101 (see process 502 and FIG. 6). This bulk semiconductor substrate 101 can be, for example, a bulk silicon substrate or a bulk semiconductor substrate of some other suitable semiconductor material. The bulk semiconductor substrate 101 can have a first surface (also referred to herein as bottom surface) and a second surface (also referred to herein as a top surface) opposite the first surface.

The method can further include forming isolation regions 105 that extend into the semiconductor substrate 101 from the top surface (see process 504 and FIG. 7). The isolation regions 105 can be, for example, shallow trench isolation (STI) regions formed using conventional STI formation techniques. That is, trenches can be formed (e.g., lithographically patterned and etched) to extend into the semiconductor substrate 101 from the top surface and to define the boundaries of and, particularly, to laterally surround one or more device sections 108 in an upper portion 104 of the semiconductor substrate 101 (e.g., in areas B and C). One or more layers of isolation material (e.g., silicon dioxide, silicon nitride, silicon oxynitride, etc.) can be deposited to fill the trenches and a chemical mechanical polishing (CMP) process can be performed to remove any of the isolation material from above the top surface of the semiconductor substrate 101. For purposes of illustration, two device sections 108 are shown: one on which a diode string 110B-2 can be formed and another within which a diode string 110C-2 can be formed. It should be understood additional device sections 108 can be defined in the upper portion and used for the formation of additional devices.

The method can further include processing the semiconductor substrate 101 so that it includes a first portion 102 (also referred to herein as a lower portion) adjacent to the bottom surface, a second portion 104 (also referred to herein as an upper portion) adjacent to the top surface, and a third portion 103 (also referred to herein as a high resistance portion) between the lower portion 102 and the upper portion 104 (e.g., just below the STI regions 105 and the device section(s) 108 in areas A-C) (see process 506 and FIG. 8). The high resistance portion 103 can be formed, for example, by performing an ion implantation process to implant an inert dopant into the semiconductor substrate between the bottom and top surfaces to modify the crystalline structure (e.g., amorphize) a middle portion of the semiconductor substrate. For purposes of this disclosure, an inert dopant refers to a dopant species that is generally not considered to be chemically reactive (i.e., that is neutral) at least with respect to the monocrystalline semiconductor material (e.g., monocrystalline silicon) within which it is implanted during processing, that is capable of modifying the crystalline structure of that monocrystalline semiconductor material during the implantation process (e.g., to create an amorphous region), that doesn't completely prevent recrystallization of the doped region during a subsequent rapid thermal anneal process (RTA) (e.g., to create poly and/or monocrystalline region(s)), and that doesn't significantly impact the electrical properties of the resulting poly and/or monocrystalline region(s). Such inert dopants include, but are not limited to, inert gases (also referred to as noble gases) (e.g., argon, xenon, helium, neon, krypton, radon, etc.), silicon, or any other suitable inert dopant. The method can further include performing a recrystallization anneal during which the amorphized portion begins to recrystallize from the top down and the bottom up and, as a result, a defect layer (i.e., the high resistance portion 103) is formed. This defect layer can be polycrystalline or amorphous in structure and can include imperfections in the regular spacing of atoms that make up the semiconductor material. These imperfections form traps and, specifically, locations within the semiconductor substrate that restrict movement of charge carriers (i.e., electrons and holes) and, thus, increase resistance as compared to the monocrystalline lower portion 102 of the semiconductor substrate 101 below and the monocrystalline upper portion 104 of the semiconductor substrate 101 above.

The method can further include performing one or more dopant implantation processes to form one or more doped well regions within one or more of the device sections 108 (see process 508). The well regions can be doped to have P-type conductivity or N-type conductivity at a relatively low conductivity level (e.g., to be a Pwell or Nwell).

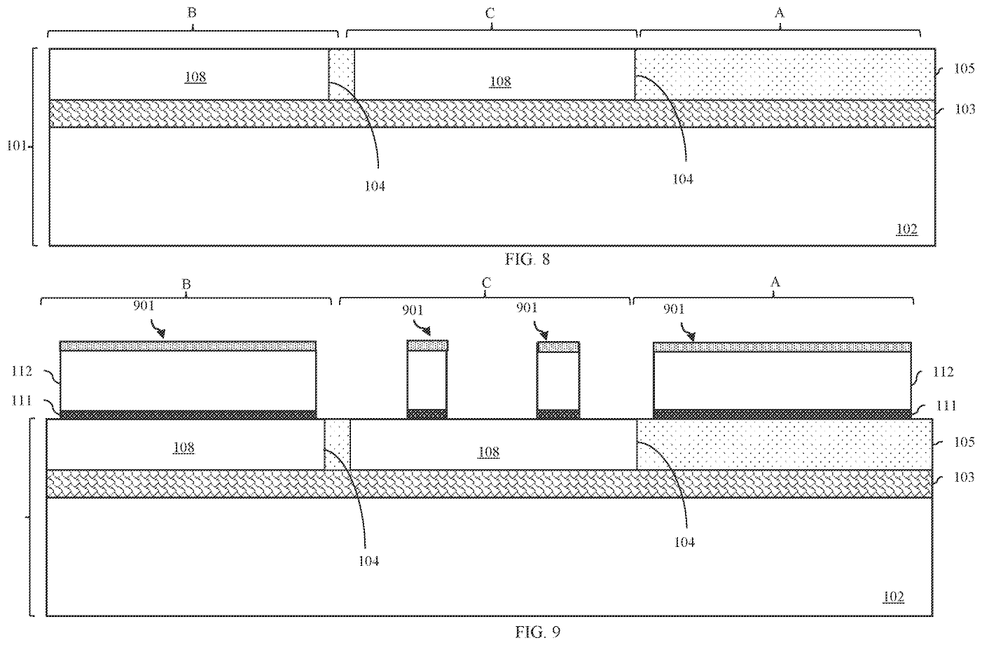

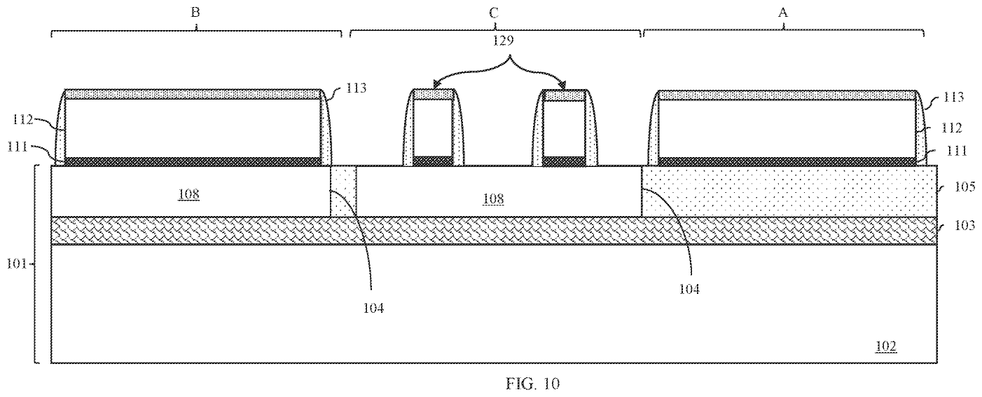

The method can further include forming at least one device and, particularly, at least one diode or multiple series-connected devices and, particularly, multiple series-connected diodes in a diode string. As mentioned above, the description and figures illustrate formation of multiple sets of series-connected diodes (i.e., diode strings) on an STI region 105 in area A, on a device section 108 in area B and within a device section 108 in area C (see process 510 and FIGS. 9-15).

Process 510 can include depositing a dielectric layer 111 on the top surface of the semiconductor substrate 101 and, particularly, over the STI regions 105 and device sections 108 and further depositing a polycrystalline semiconductor layer 112 on the dielectric layer 111. The polycrystalline semiconductor layer 112 and the dielectric layer 111 can be lithographically patterned and etched during processing to form multiple elongated rectangular shaped stacks 901 of layers. The stacks 901 have opposing sidewalls and opposing end walls. That stacks 901 can include a device stack on the STI region 105 in area A and a device stack on the device section 108 in area B. The stacks 901 can also include isolation stacks on the device section 108 in area C. It should be noted that diode strings will be formed, as discussed below, in the polycrystalline semiconductor layer 112 in the device stacks on the STI region 105 in area A and on the device section 108 in area B, whereas the isolation stacks formed on the device section 108 in area C will function as isolation structures (e.g., dummy gate structures) that will prevent silicide formation over the PN/PIN junctions of each diode within the device section below. In any case, within these stacks 901, the dielectric layer 111 and the polycrystalline semiconductor layer 112 can be the same layers used in the formation of other devices (e.g., resistors) or components (e.g., gate structures of field effect transistors (FETs)) formed elsewhere on the semiconductor substrate 101. Thus, for example, in some embodiments the dielectric layer 111 can include one or more layers of gate dielectric material including, but not limited to, silicon dioxide, silicon oxynitride, a high-K gate dielectric (e.g., hafnium oxide, hafnium silicon oxide, hafnium silicon oxynitride, hafnium aluminum oxide, aluminum oxide, tantalum oxide, zirconium oxide, etc.) or any other suitable gate dielectric material. The polycrystalline semiconductor layer 112 can be, for example, a polycrystalline semiconductor material suitable for use as a gate conductor material (when doped) (e.g., a polysilicon, polysilicon germanium, etc.).

Process 510 can further include forming sidewall spacers 113 on vertical surfaces of the stacks 901 using conventional sidewall spacer formation techniques. For example, a conformal dielectric spacer material layer (e.g., a silicon dioxide layer, a silicon oxynitride layer, etc.) can be deposited over the partially completed structure. Then, a selective anisotropic etch process can be performed so as to remove the spacer material layer from any horizontal surfaces and so that the remaining portions of the spacer material layer on any vertical surfaces form sidewall spacers 113.

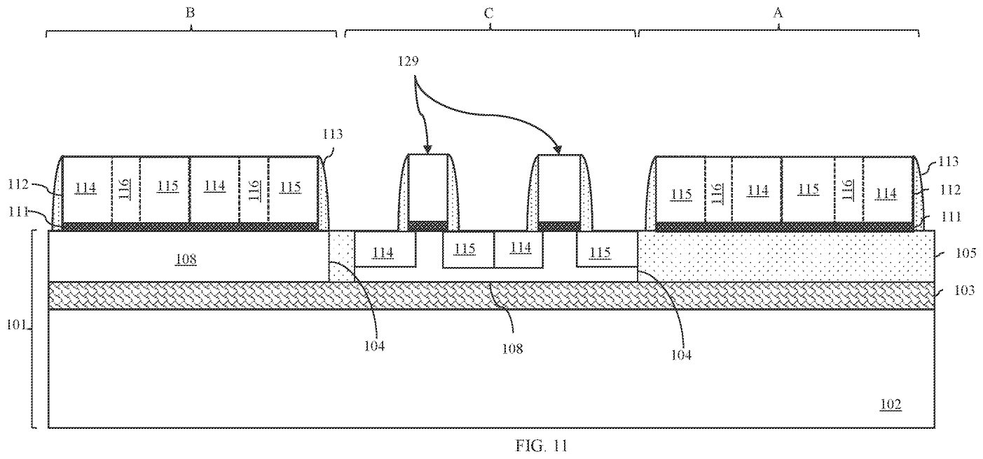

Process 510 can further include performing a series of masked dopant implantation processes to form the N-type semiconductor regions 114 and P-type semiconductor regions 115 for the diode strings in area A, area B, and area C (see FIG. 12).

For example, area A, area B, and the semiconductor material on one side of each stack 901 in area C can be masked with a first mask and processing can be performed in order to form one type of semiconductor region (e.g., the N-type semiconductor regions 114) for the diode string within that area C. The first mask can be removed and area A, area B, and the semiconductor material on the other side of each stack 901 in area C can be masked with a second mask and processing can be performed in order to form another type of semiconductor region (e.g., the P-type semiconductor regions 115) for the diode string within that area C. In this case, the N-type semiconductor region 114 and the P-type semiconductor region 115 of each diode within the device section 108 of area C will separated by semiconductor material, which is below a corresponding stack and which is either undoped, part of a Pwell or part of an Nwell. Optionally, formation of the semiconductor regions 114 and 115 in area C can be performed concurrently with formation of source/drain regions of FETs else on the substrate. Techniques can include, for example, dopant implantation or, alternatively, trench formation and in situ-doped selective epitaxial deposition.

Subsequently, area C and first portions of the polycrystalline semiconductor layers 112 in the stacks 901 on the STI region 105 in area A and on the device section 108 in area B can be masked using a third mask and a dopant implantation processing can be performed in order to form one type of semiconductor region (e.g., the N-type semiconductor regions 114) within the polycrystalline semiconductor layers 112 in the stacks 901 in areas A and B. The third mask can be removed and area C and second portions of the polycrystalline semiconductor layers 112 in the stacks 901 on the STI region 105 in area A and on the device section 108 in area B can be masked using a fourth mask and dopant implantation processing can be performed in order to form another type of semiconductor region (e.g., the P-type semiconductor regions 115) for the diode strings within the polycrystalline semiconductor layer 112 in areas A and B. Optionally, the third and fourth masks can be patterned so that an additional semiconductor region 116 separates the N-type and P-type semiconductor regions 114-115 of a given diode and is an intrinsic semiconductor region. Optionally, the third and fourth masks can be patterned so that the N-type and P-type semiconductor regions 114-115 of two adjacent diodes are immediately adjacent to each other, as illustrated. Optionally, the third and fourth masks can be patterned so that the N-type and P-type semiconductor regions 114-115 of two adjacent diodes are physically separated (e.g., by an additional semiconductor region and, particularly, an intrinsic semiconductor region).

Alternatively, dopant implantation processes to form the N-type semiconductor regions 114 within the polycrystalline semiconductor layers 112 in the stacks 901 on the STI region 105 in area A and in the device section 108 in area B can be performed concurrently with dopant implantation processes used to form the N-type semiconductor regions 114 within the device section 108 in area C. Additionally, dopant implantation processes to form the P-type semiconductor regions 115 within the polycrystalline semiconductor layers 112 in the stacks 901 on the STI region 105 in area A and in the device section 108 in area B can be performed concurrently with dopant implantation processes used to form the P-type semiconductor regions 115 within the device section 108 in area C.

Alternatively, any other suitable techniques could be employed to dope the N-type semiconductor regions 114 and the P-type semiconductor regions 115 in the polycrystalline semiconductor layers 112 of the stacks 901 on the STI region 105 in area A and on the device section in area B and to also dope the N-type semiconductor regions 114 and the P-type semiconductor regions 115 in the device section 108 in area C.

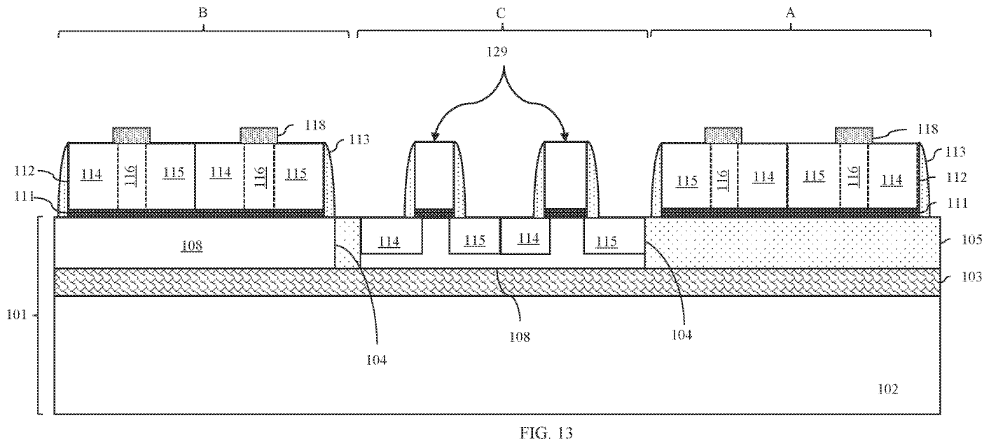

The method can further include forming isolation structures on the top surfaces of the diode strings with each isolation structure extending across an interface between the P-type semiconductor region 115 and the N-type semiconductor region 114 of a given diode (e.g., across the PN junction or PIN junction of the given diode) in each diode string (see process 512 and FIG. 13). For example, a dielectric layer (e.g., a salicide block layer or other dielectric layer) can be deposited and lithographically patterned and etched to form discrete isolation structures 118. The dielectric layer can be, for example, a silicon nitride (SiN) layer, silicon carbon nitride (SiCN) layer, a silicon oxynitride (SiON) layer, etc. Optionally, instead of forming isolation structures 118, as described above, on the top surface of the device section 108 in area C above the PN or PIN junction of each diode, the stacks 901 can remain in place as dummy gate structures/isolation structures 129 that serve this function.

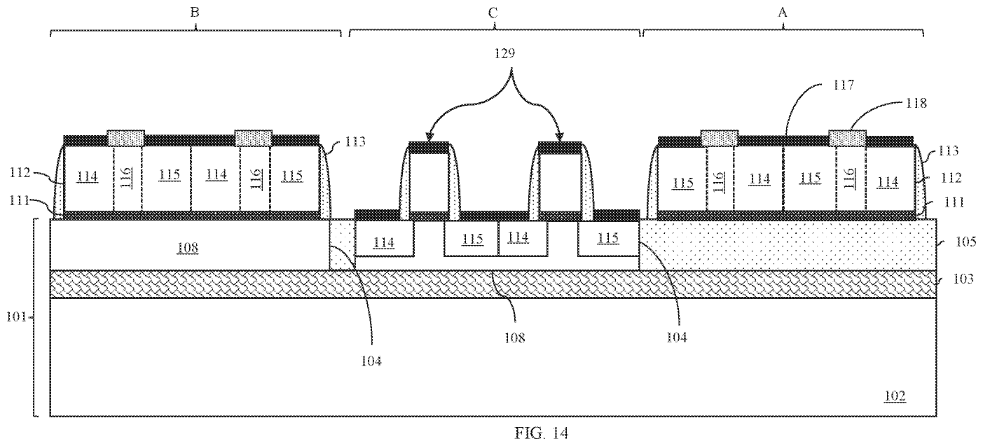

The method can further include forming metal silicide layers 117 on each P-type semiconductor region 115 and each N-type semiconductor region 114 of each diode in each diode string (see process 514 and FIG. 14). The isolation structures 118 (or 129) as discussed above will block silicide formation over the interface between the P-type semiconductor region 115 and N-type semiconductor region 114 of any given diode. However, continuous silicide layers can be formed across each interface between a P-type semiconductor region 115 of one diode and the N-type semiconductor region 114 of an adjacent diode in a diode string, thereby electrically connecting the adjacent diodes. These metal silicide layers 117 can be, for example, layers of cobalt silicide (CoSi), nickel silicide (NiSi), tungsten silicide (WSi), titanium silicide (TiSi), or any other suitable metal silicide material. Such silicide layers can be formed using a conventional salicide process.

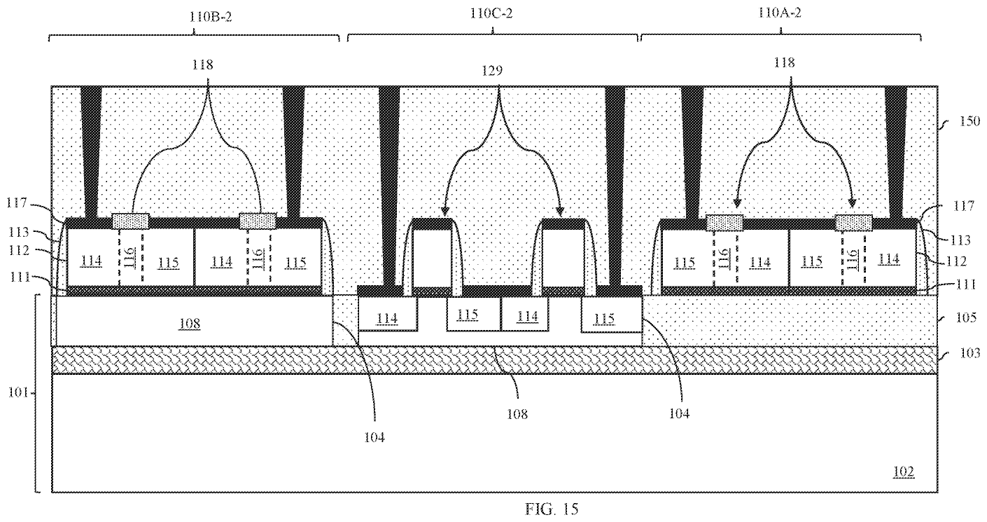

The method can further include performing MOL processing (see process 516 and FIG. 15). The MOL processing can include forming one or more layers of MOL dielectric material 150 covering the partially completed structure. These layer(s) of MOL dielectric material 150 can include, but are not limited to, a relatively thin conformal dielectric layer (also referred to herein as an etch stop layer). This relatively thin conformal dielectric layer can be made of silicon nitride or some other suitable etch stop material. These layer(s) of MOL dielectric material 150 can also a blanket layer of interlayer dielectric (ILD) material. This ILD material can be, for example, silicon dioxide, doped silicon glass (e.g., phosphosilicate glass (PSG) or borophosphosilicate glass (BPSG)), or any other suitable ILD material. MOL processing can also include forming MOL contacts. The MOL contacts can include, for example, cathode contacts 119a extending essentially vertically through the MOL dielectric material 150 to an N-type semiconductor region 114 at one end of each diode string 110A-2, 110B-2, and 110C-2 and anode contacts 119b extending essentially vertically through the MOL dielectric material 150 to the P-type semiconductor region 116 at the opposite end of each diode string 110A-2, 110B-2, and 110C-2. Such MOL contacts can be formed using conventional contact formation techniques.

The method can further include performing BEOL processing (see process 518 and FIG. 4B). The BEOL processing can be performed to electrically connect the diode strings to other on-chip components through MOL contacts and wires in the back-end-of-the-line (BEOL) metal levels (MI-Mx).

It should be understood that in the structures and method described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, the above description refers to semiconductor regions or layers being either P-type semiconductor regions or layers or N-type semiconductor regions or layers. It should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity (i.e., to form a P-type semiconductor region or layer), whereas a silicon-based semiconductor material is typically doped a Group V dopant, such as arsenic (As), phosphorous (P) or antimony (Sb), to achieve N-type conductivity (i.e., to form an N-type semiconductor region or layer). A gallium nitride (GaN)-based semiconductor material is typically doped with magnesium (Mg) to achieve P-type conductivity (i.e., to form a P-type semiconductor region or layer) and with silicon (Si) or oxygen to achieve N-type conductivity (i.e., to form an N-type semiconductor region or layer). Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a”, “an” and “the” are intended to include the plural forms as well, unless the context clearly indicates otherwise. Additionally, as used herein, the terms “comprises” “comprising”, “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor substrate having a first surface and a second surface opposite the first surface, wherein the semiconductor substrate comprises:
a first portion adjacent to the first surface;
a second portion adjacent to the second surface; and
a third portion between the first portion and the second portion, wherein the third portion has higher resistance than the first portion and the second portion; and
a diode adjacent to the second surface and separated from the first portion at least by the third portion.

2. The structure of claim 1, wherein the third portion is a trap-rich layer.

3. The structure of claim 1,
wherein the diode comprises: a P-type semiconductor region; and an N-type semiconductor region positioned laterally adjacent to the P-type semiconductor region, and
wherein the structure further comprises:
an isolation structure extending across an interface between the P-type semiconductor region and the N-type semiconductor region; and
silicide layers on the P-type semiconductor region and the N-type semiconductor region and separated by the isolation structure.

4. The structure of claim 3, wherein the P-type semiconductor region and the N-type semiconductor region are separated by one of:
an intrinsic semiconductor region; and
an additional semiconductor region having one of P-type conductivity at a lower conductivity level than the P-type semiconductor region and N-type conductivity at a lower conductivity level than the N-type semiconductor region.

5. The structure of claim 3, further comprising:
an isolation region extending from the second surface through the second portion toward the third portion;
a dielectric layer above and immediately adjacent to the isolation region;
a polycrystalline semiconductor layer on the dielectric layer, and
wherein the P-type semiconductor region and the N-type semiconductor region are within the polycrystalline semiconductor layer.

6. The structure of claim 3, further comprising:
an isolation region extending from the second surface through the second portion toward the third portion, wherein the isolation region is positioned laterally adjacent to a device section of the second portion;
a dielectric layer above and immediately adjacent to the device section; and
a polycrystalline semiconductor layer on the dielectric layer,
wherein the P-type semiconductor region and the N-type semiconductor region are within the polycrystalline semiconductor layer.

7. The structure of claim 3, further comprising an isolation region extending from the second surface through the second portion toward to the third portion,
wherein the isolation region is positioned laterally adjacent to a device section of the second portion, and
wherein the P-type semiconductor region and the N-type semiconductor region are within the device section.

8. A structure comprising:
a semiconductor substrate having a first surface and a second surface opposite the first surface, wherein the semiconductor substrate comprises:
a first portion adjacent to the first surface;
a second portion adjacent to the second surface; and
a third portion between the first portion and the second portion, wherein the third portion has higher resistance than the first portion and the second portion; and
series-connected diodes adjacent to the second surface and separated from the first portion at least by the third portion.

9. The structure of claim 8, wherein the third portion is a trap-rich layer.

10. The structure of claim 8,
wherein each diode of the series-connected diodes comprises: a P-type semiconductor region; and an N-type semiconductor region positioned laterally adjacent to the P-type semiconductor region, and
wherein the structure further comprises, for each diode of the series-connected diodes:
an isolation structure extending across an interface between the P-type semiconductor region and the N-type semiconductor region; and
silicide layers on the P-type semiconductor region and the N-type semiconductor region and separated by the isolation structure.

11. The structure of claim 10, wherein the P-type semiconductor region and the N-type semiconductor region of each diode of the series-connected diodes are separated by one of:
an intrinsic semiconductor region; and
an additional semiconductor region having one of P-type conductivity at a lower conductivity level than the P-type semiconductor region and N-type conductivity at a lower conductivity level than the N-type semiconductor region.

12. The structure of claim 10, further comprising:
an isolation region extending from the second surface through the second portion toward the third portion;
a dielectric layer above and immediately adjacent to the isolation region; and
a polycrystalline semiconductor layer on the dielectric layer,
wherein the P-type semiconductor region and the N-type semiconductor region of at least one diode of the series-connected diodes are within the polycrystalline semiconductor layer.

13. The structure of claim 10, further comprising:
an isolation region extending from the second surface through the second portion toward the third portion, wherein the isolation region is positioned laterally adjacent to a device section of the second portion;
a dielectric layer above and immediately adjacent to the device section; and
a polycrystalline semiconductor layer on the dielectric layer,
wherein the P-type semiconductor region and the N-type semiconductor region of at least one device of the series-connected diodes are within the polycrystalline semiconductor layer.

14. The structure of claim 10, further comprising an isolation region extending from the second surface through the second portion toward the third portion,
wherein the isolation region is positioned laterally adjacent to a device section of the second portion, and
wherein the P-type semiconductor region and the N-type semiconductor region of at least one diode of the series-connected diodes has the P-type semiconductor region and the N-type semiconductor region within the device section.

15. The structure of claim 8, further comprising:
an isolation region extending from the second surface through the second portion toward the third portion, wherein the isolation region is positioned laterally adjacent to a device section of the second portion; and
multiple sets of series-connected devices, wherein at least one set of the series-connected devices is on the isolation region and at least one other set of the series-connected devices is any of on the device section and in the device section.

16. The structure of claim 8, further comprising an electrostatic discharge protection structure comprising the series-connected devices.

17. A method comprising:
processing a semiconductor substrate so that a first portion adjacent to a first surface of the semiconductor substrate and a second portion adjacent to a second surface of the semiconductor substrate are separated by a third portion with a higher resistance than the first portion and the second portion; and
forming at least one diode adjacent to the second surface and separated from the first portion by the third portion.

18. The method of claim 17, further comprising forming an isolation region extending into the semiconductor substrate from the second surface such that the isolation region is positioned laterally adjacent to a device section within the second portion, wherein the processing of the semiconductor substrate forms the third portion as a trap-rich layer below the isolation region and the device section.

19. The method of claim 18, wherein the forming of the at least one diode comprises forming the at least one diode on any one of the isolation region and the device section by:
forming a dielectric layer;
forming a polycrystalline semiconductor layer on the dielectric layer;
patterning the polycrystalline semiconductor layer and the dielectric layer to form a device stack above the one of the isolation region and the device section;
forming, for each diode, a P-type semiconductor region and an N-type semiconductor region within the polycrystalline semiconductor layer of the device stack such that the P-type semiconductor region and the N-type semiconductor region are polycrystalline and such that the N-type semiconductor region is positioned laterally adjacent to the P-type semiconductor region;
forming, for each diode, an isolation structure on the polycrystalline semiconductor layer extending across an interface between the P-type semiconductor region and the N-type semiconductor region; and
forming, for each diode, silicide layers on the P-type semiconductor region and the N-type semiconductor region and separated by the isolation structure.

20. The method of claim 18, wherein the forming of the at least one diode comprises:
forming, for each diode, a P-type semiconductor region and an N-type semiconductor region within the device section such that the P-type semiconductor region and the N-type semiconductor region are monocrystalline and such that the N-type semiconductor region is positioned laterally adjacent to the P-type semiconductor region;
forming, for each diode, an isolation structure on the device section extending across an interface between the P-type semiconductor region and the N-type semiconductor region; and
forming, for each diode, silicide layers on the P-type semiconductor region and the N-type semiconductor region and separated by the isolation structure.
